(19) United States
(12) Patent Application Publication
(10) Pub. No.: US 2025/0227969 A1
(43) Pub. Date: Jul. 10, 2025

(54) SEMICONDUCTOR MEMORY DEVICE

(71) Applicant: SAMSUNG ELECTRONICS CO., LTD., Suwon-si (KR)

(72) Inventors: Daehyun KIM, Suwon-si (KR); Chunhyung CHUNG, Suwon-si (KR); Hyojung KIM, Suwon-si (KR); Harim CHOI, Suwon-si (KR)

(73) Assignee: SAMSUNG ELECTRONICS CO., LTD., Suwon-si (KR)

(21) Appl. No.: 18/760,574

(22) Filed: Jul. 1, 2024

(30) Foreign Application Priority Data
Jan. 8, 2024 (KR) 10-2024-0003113

(51) Int. Cl. H01L 29/06; H01L 21/762; H01L 29/78; H10B 12/00

(52) U.S. Cl. CPC H10D 62/124; H01L 21/76237; H10B 12/482; H10B 12/488; H10D 30/62

(57) ABSTRACT

A semiconductor memory device includes a substrate having active areas defined by a device separation trench, a device separation material layer that fills the device separation trench and that is formed of a first material, a word line trench that crosses the active areas and the device separation material layer and that extends in a first horizontal direction, a gate dielectric layer covering an inner wall of the word line trench, and a word line that fills a portion of the word line trench on the gate dielectric layer. The device separation material layer includes a doped layer inside the device separation material layer. The doped layer includes a second material different from the first material.

### CROSS-REFERENCE TO RELATED APPLICATION

This application is based on and claims priority under 35 U.S.C. § 119 to Korean Patent Application No. 10-2024-0003113, filed on Jan. 8, 2024 in the Korean Intellectual Property Office, the disclosure of which being incorporated by reference herein in its entirety.

### BACKGROUND

Devices and apparatuses consistent with the present disclosure relate to a semiconductor memory device and, more particularly, to a semiconductor memory device including buried word lines.

Recently, as the degree of integration of semiconductor memory devices has gradually increased, the structure of semiconductor memory devices with a buried channel array transistor (BCAT) in the form of a plurality of word lines buried in a substrate has been proposed. Accordingly, various studies are being conducted to improve and stabilize the operation and reliability of the BCAT.

### SUMMARY

It is an aspect to provide a semiconductor memory device with improved reliability.

According to an aspect of one or more embodiments, there is provided a semiconductor memory device comprising a substrate having a plurality of active areas defined by a device separation trench; a device separation material layer that fills the device separation trench and that is formed of a first material; a word line trench that crosses the plurality of active areas and the device separation material layer and that extends in a first horizontal direction; a gate dielectric layer covering an inner wall of the word line trench; and a word line that fills a portion of the word line trench on the gate dielectric layer, wherein the device separation material layer comprises a doped layer inside the device separation material layer, the doped layer including a second material different from the first material.

According to another aspect of one or more embodiments, there is provided a semiconductor memory device comprising a substrate including a cell array area and a periphery circuit area; a plurality of active areas defined by a device separation trench in the cell array area; a device separation material layer that fills the device separation trench; a word line trench that crosses the plurality of active areas and the device separation material layer and that extends in a first horizontal direction; a gate dielectric layer covering an inner wall of the word line trench; and a word line that fills a portion of the word line trench on the gate dielectric layer, wherein the device separation material layer comprises a recess area formed in a vertical direction that is perpendicular to the substrate, and the recess area is filled with an ion implantation layer.

According to yet another aspect of one or more embodiments, there is provided a semiconductor memory device comprising a substrate having a cell array area including a plurality of active areas defined by a device separation trench, a periphery circuit area in which at least one logic active area is defined, and an interface area between the cell array area and the periphery circuit area; a device separation material layer that fills the device separation trench in the cell array area; a plurality of word lines respectively crossing the plurality of active areas and extending in a first horizontal direction; a plurality of bit lines respectively arranged in the plurality of active areas and extending in a second horizontal direction that is orthogonal to the first horizontal direction; a gate line arranged in the at least one logic active area; a plurality of buried contacts that fill a lower side portion of a space between the plurality of bit lines and that are respectively connected to the plurality of active areas; a plurality of landing pads that fill an upper side portion between the plurality of bit lines and that respectively extend onto the plurality of bit lines; and a plurality of capacitor structures including an upper electrode, a plurality of lower electrodes respectively in contact with the plurality of landing pads, and a capacitor dielectric layer arranged between the upper electrode and the plurality of lower electrodes, wherein the device separation material layer comprises an ion implantation layer that extends into the device separation material layer to a first depth from an upper surface of the device separation material layer toward the substrate, and wherein a horizontal cross-section of the ion implantation layer is within a horizontal cross-section of the device separation material layer, and the first depth is less than a thickness of the device separation material layer in a vertical direction.

### BRIEF DESCRIPTION OF THE DRAWINGS

Various embodiments will be more clearly understood from the following detailed description taken in conjunction with the accompanying drawings, in which:

FIG. 1 is a layout diagram of a semiconductor memory device according to an embodiment;

FIG. 2 is an enlarged layout diagram of region P in FIG. 1, according to an embodiment;

FIGS. 3A through 12D are cross-sectional views illustrating a method of manufacturing a semiconductor memory device, according to various embodiments; and

FIGS. 13A through 13D are cross-sectional views of a semiconductor memory device according to various embodiments.

### DETAILED DESCRIPTION

Hereinafter, various embodiments are described in detail with reference to accompanying drawings and diagrams. Identical reference numerals are used for the same constituent components in the drawings, and duplicate descriptions thereof are omitted for conciseness. As used in this specification, the phrase “at least one of A, B, or C” includes within its scope “only A”, “only B”, “only C”, “A and B”, “B and C”, “A and C”, and “A, B, and C”.

Because various changes may be applied to the various embodiments, some embodiments are illustrated in the diagrams and described in detail. However, this description of some embodiments is not intended to limit the scope to particular modes of practice, and it is to be appreciated that all changes, equivalents, and substitutes, which do not depart from the spirit and technical scope of the present disclosure, are encompassed in the appended claims. In the description of the various embodiments, certain detailed explanations of the related art are omitted when it is deemed that they may unnecessarily obscure the various embodiments.

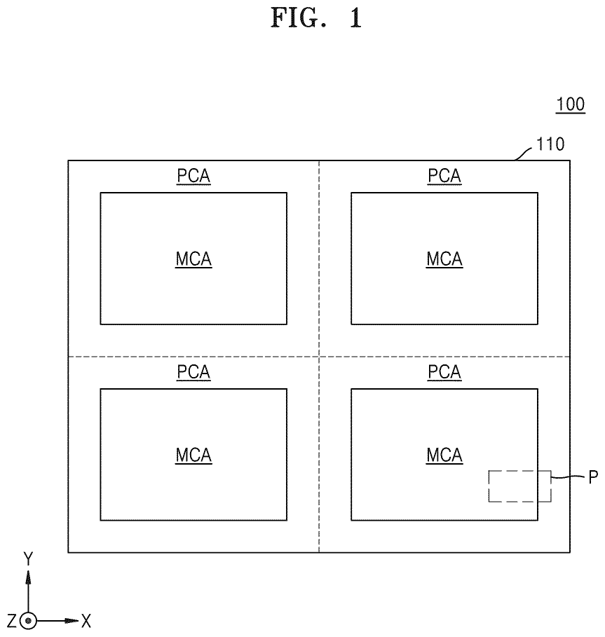

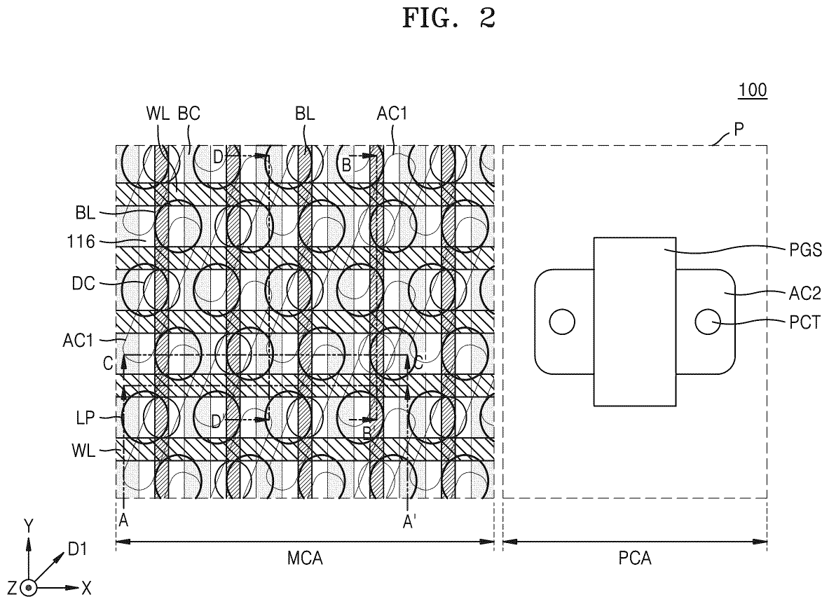

FIG. 1 is a layout diagram of a semiconductor memory device 100 according to an embodiment, and FIG. 2 is an enlarged layout diagram of region P in FIG. 1, according to an embodiment.

Referring to FIGS. 1 and 2, the semiconductor memory device 100 may include a substrate 110 including a cell array area MCA and a periphery circuit area PCA. In some embodiments, the substrate 110 may include a plurality of MCAs and a plurality of PCAs. The cell array area MCA may include a memory cell area of a dynamic random access memory (DRAM) device, and the periphery circuit area PCA may include a core area or a periphery circuit area of the DRAM device. For example, the cell array area MCA may include a cell transistor and a capacitor structure connected to the cell capacitor, and the periphery circuit area PCA may include a periphery circuit transistor for transferring signals and/or power to the cell transistor included in the cell array area MCA. In some embodiments, the periphery circuit transistor may constitute various circuits, such as a command decoder, a control logic, an address buffer, a row decoder, a column decoder, a sense amplifier, and/or a data input/output circuit.

A device separation trench and an area separation trench may be formed in the substrate 110, and a plurality of device separation layers may be formed in the device separation trench and the area separation trench. A plurality of first active areas AC1 may be defined in the cell array area MCA of the substrate 110 by some device separation layers, and a plurality of second active areas AC2 may be defined in the periphery circuit area PCA by the other device separation layers.

As illustrated in FIG. 2, in the cell array area MCA, each of the plurality of first active areas AC1 may be arranged to have a major axis in a first diagonal direction (D1 direction) inclined with respect to a first horizontal direction (X direction) and a second horizontal direction (Y direction). A plurality of word lines WL may extend in parallel with each other in the first horizontal direction (X direction) across the plurality of first active areas AC1. A plurality of bit lines BL may extend in parallel with each other in the second horizontal direction (Y direction) on the plurality of word lines WL. The plurality of bit lines BL may be connected to the plurality of first active areas AC1 via bit line contacts DC, respectively.

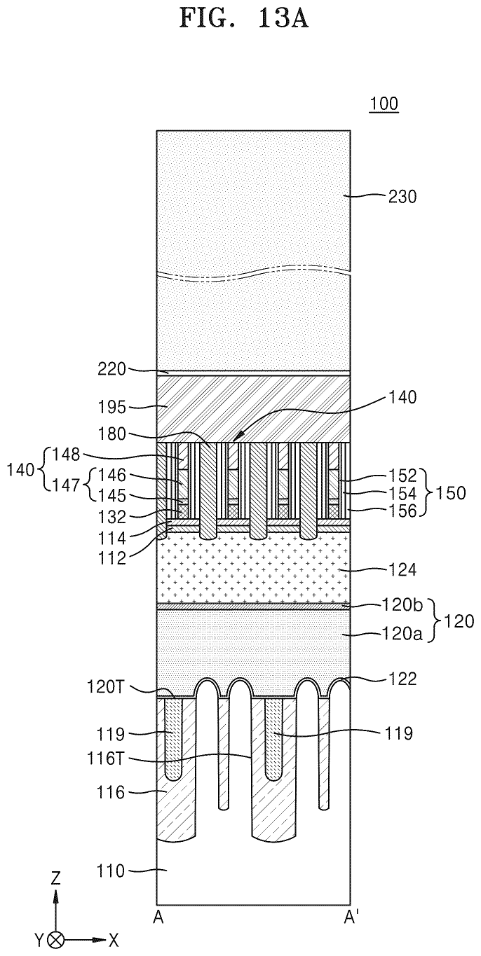

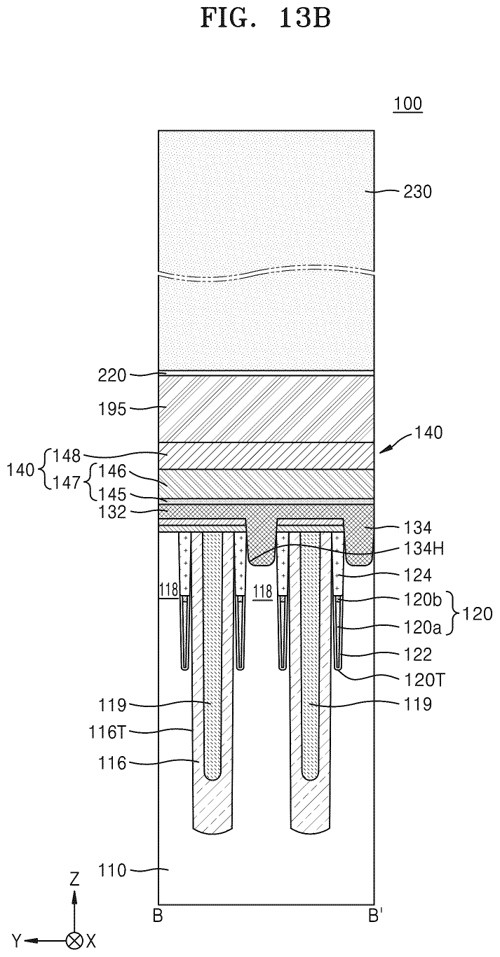

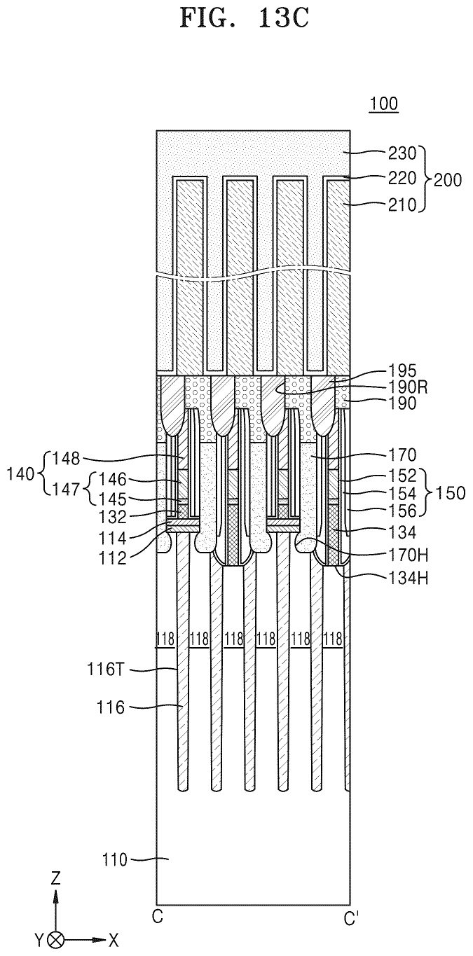

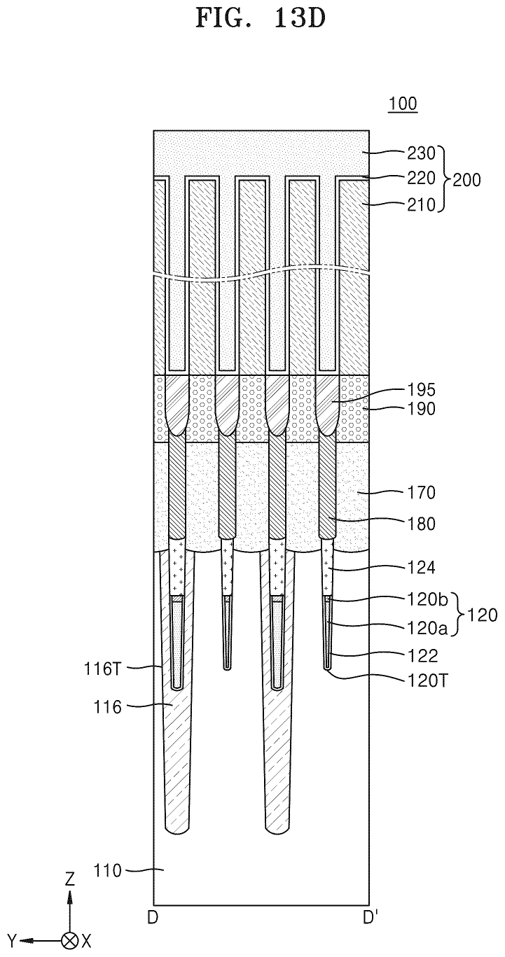

A plurality of buried contacts BC may be disposed between two adjacent bit lines BL among the plurality of bit lines BL. A plurality of landing pads LP may be respectively formed on the plurality of buried contacts BC. The plurality of buried contacts BC and the plurality of landing pads LP may connect a lower electrode (refer to 210 in FIGS. 13A through 13D) of a capacitor structure (refer to 200 of FIGS. 13A through 13D) formed on an upper portion of the plurality of bit lines BL to the first active area AC1. In an embodiment, each of the plurality of landing pads LP may be arranged to partially overlap the buried contact BC and the bit line BL.

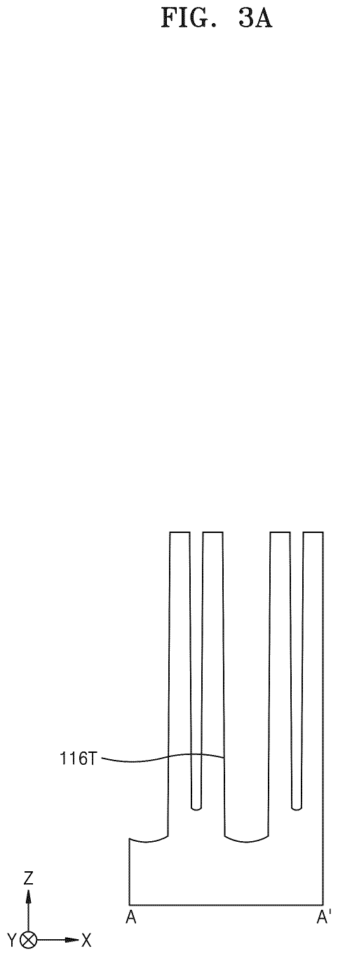

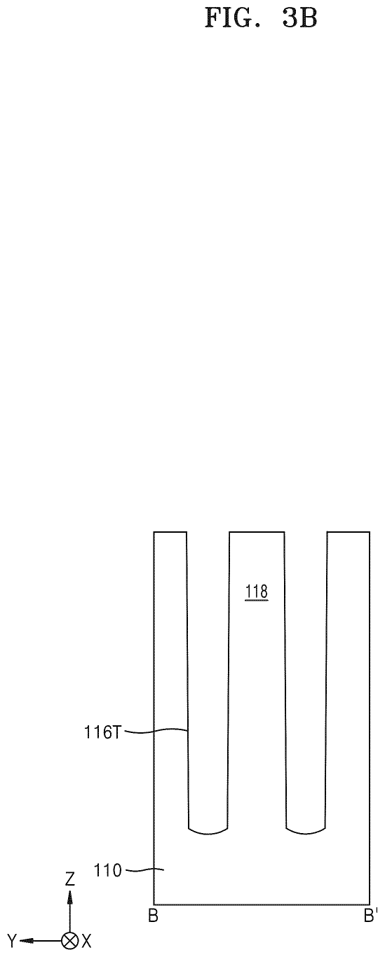

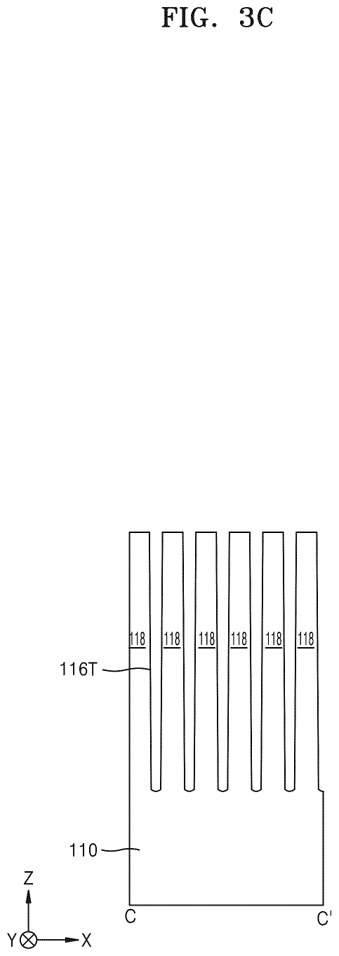

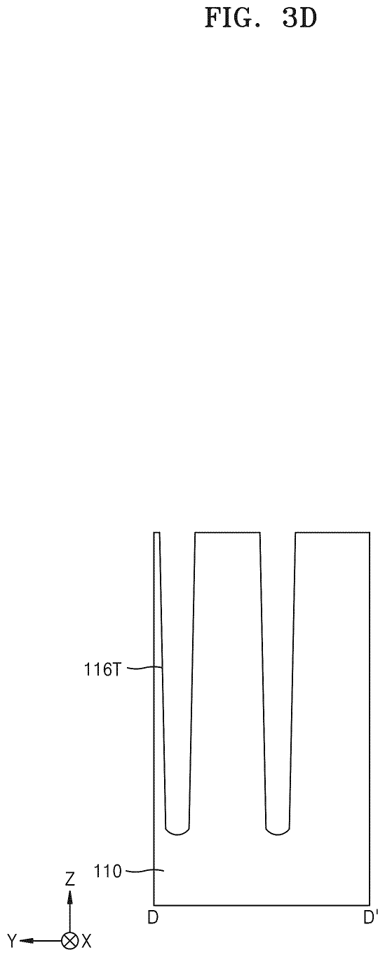

FIGS. 3A through 3D, 4A through 4D, 5A and 5B, 6A and 6B, 7A through 7D, 8A through 8D, 9A through 9D, 10A through 10D, 11A through 11D, and 12A through 12D are cross-sectional views illustrating a method of manufacturing the semiconductor memory device 100, according to some embodiments, and FIGS. 13A through 13D are cross-sectional views of the semiconductor memory device 100 according to some embodiments. FIGS. 3A, 4A, 5A, 6A, 7A, 8A, 9A, 10A, 11A, 12A, and 13A are cross-sectional views taken along line A-A′ in FIG. 2. FIGS. 3B, 4B, 5B, 6B, 7B, 8B, 9B, 10B, 11B, 12B, and 13B are cross-sectional views taken along line B-B′ in FIG. 2. FIGS. 3C, 4C, 5C, 6C, 7C, 8C, 9C, 10C, 11C, 12C, and 13C are cross-sectional views taken along line C-C′ in FIG. 2. FIGS. 3D, 4D, 5D, 6D, 7D, 8D, 9D, 10D, 11D, 12D, and 13D are cross-sectional views taken along line D-D′ in FIG. 2.

Referring to FIGS. 3A through 3D together, by removing a portion of the substrate 110, a device separation trench 116T and an area separation trench (not illustrated) may be formed in the substrate 110. The device separation trench 116T may be formed in the cell array area MCA illustrated in FIG. 2, and the area separation trench (not illustrated) may be formed in the periphery circuit area PCA illustrated in FIG. 2.

The substrate 110 may include, for example, silicon (Si), crystalline Si, polycrystalline Si, or amorphous Si. In other embodiments, the substrate 110 may include a semiconductor element such as germanium (Ge), or at least one compound semiconductor, such as silicon germanium (SiGe), silicon carbide (SiC), gallium arsenide (GaAs), indium arsenide (InAs), and/or indium phosphide (InP). In some embodiments, the substrate 110 may have a silicon on insulator (SOI) structure. For example, the substrate 110 may include a buried oxide (BOX) layer. The substrate 110 may include a conductive area, for example, a well doped with impurities, or a structure doped with impurities.

A plurality of active areas 118 may be defined in the cell array area MCA in the substrate 110 by the device separation trench 116T, and a plurality of logic active areas (not illustrated) may be defined in a periphery area PCA in the substrate 110. In some embodiments, the plurality of active areas 118 and/or the plurality of logic active areas defined by the device separation trench 116T may be formed by using an extreme ultraviolet (EUV) lithography process. The active area 118 may have a relatively long island shape having both a minor axis and a major axis in a plan view, similar to the first active area AC1 illustrated in FIG. 2. The plurality of active areas 118 may be arranged in a row in a diagonal direction with respect to the first horizontal direction (X direction) and the second horizontal direction (Y direction) and may also be arranged in a row in the second horizontal direction (Y direction). The logic active area may have a rectangular shape in a plan view, but is not limited thereto and, in some embodiments, the logic active area may have other planar shapes. The plurality of active areas 118 and the plurality of logic active areas may be spaced apart from each other with the area separation trench arranged therebetween.

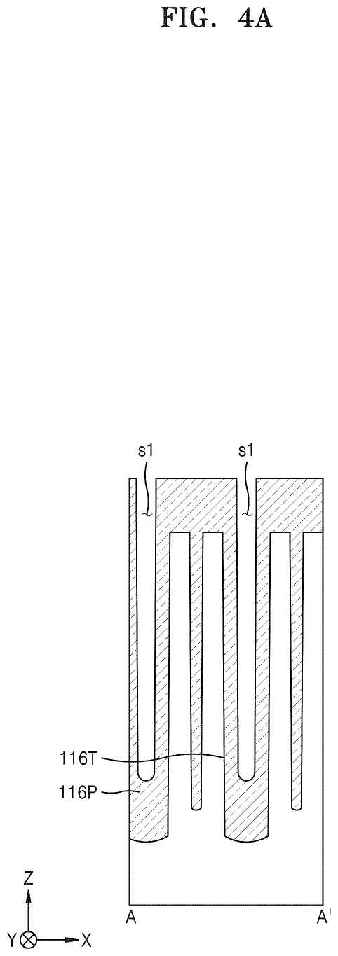

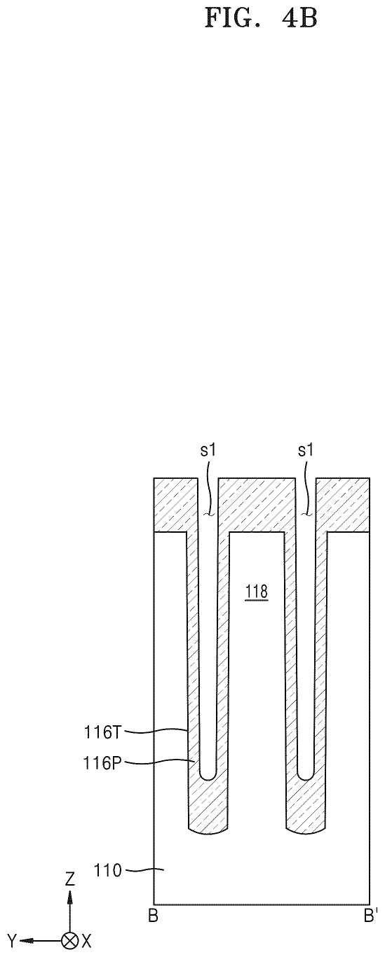

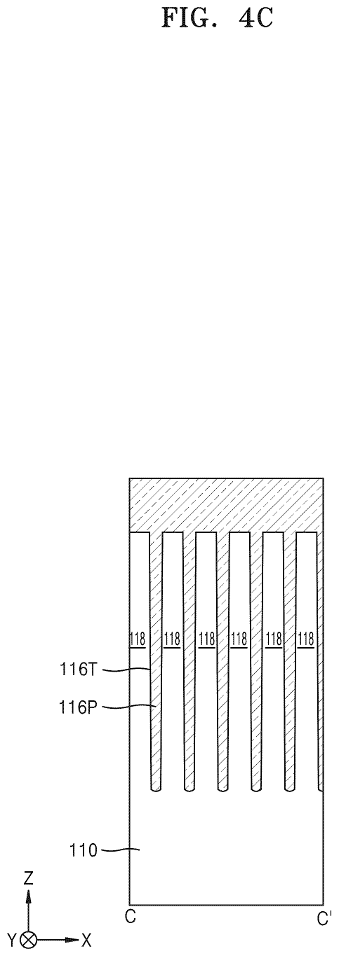

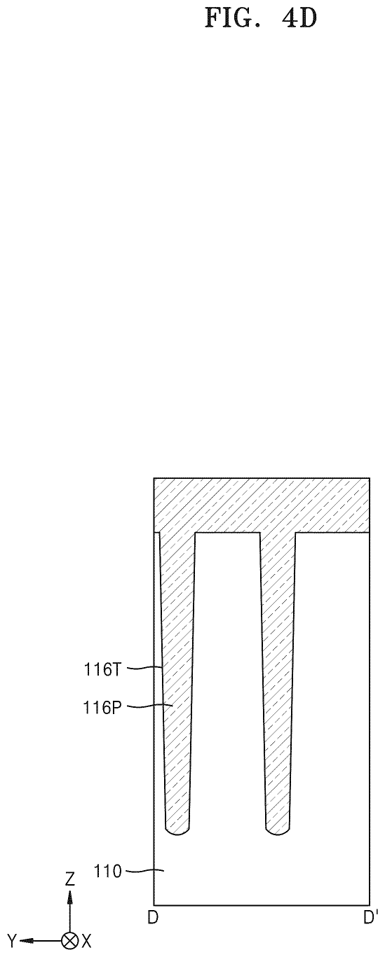

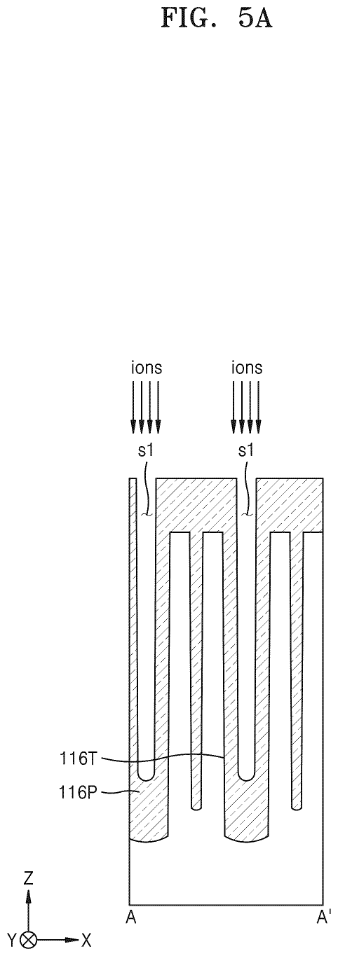

Referring to FIGS. 4A through 4D together, a device separation material layer 116P that fills portions of the area separation trench and the device separation trench 116T may be formed. The device separation material layer 116P may include a material including at least one of, for example, silicon oxide, silicon nitride, or silicon oxynitride. For example, the device separation material layer 116P may include a single layer including an oxide layer. In some embodiments, the device separation material layer 116P may include silicon oxide.

The device separation material layer 116P may be formed to fill the inside of the device separation trench 116T by using an atomic layer deposition (ALD) process. The device separation material layer 116P has a good step coverage because one layer is deposited at every step, but a thin seam may remain after the ALD process is completed. In other words, the device separation material layer 116P may be formed to generally fill the device separation trench 116T except for a thin seam portion of the device separation trench 116T. As illustrated in FIGS. 4A and 4B, in some embodiments, the thin seam may be left as an empty space s1 (e.g., a recess area) in a direction perpendicular to the substrate 110. In some embodiments, a width of a horizontal cross-sectional area of the recess area may be not greater than a width of a horizontal cross-sectional area of the device separation trench 116T, and an upper surface of the recess area may be coplanar with an upper surface of the device separation trench 116T. Ion some embodiments, a width of the recess area in the vertical direction may be less than a width of the device separation trench 116T in the vertical direction.

According to various embodiments, a “level” or a “vertical level” may denote a height or location in a vertical direction (Z direction) with respect to a main surface or an upper surface of the substrate 110. In other words, that a position is at an “identical level” or a “constant level” may denote that a position is at an identical height or a constant height with respect to the main surface of the substrate 110 in the vertical direction (Z direction), and that a position is at a low/high level may denote that a position is at a less/greater height with respect to the main surface or the upper surface of the substrate 110 in the vertical direction (Z direction).

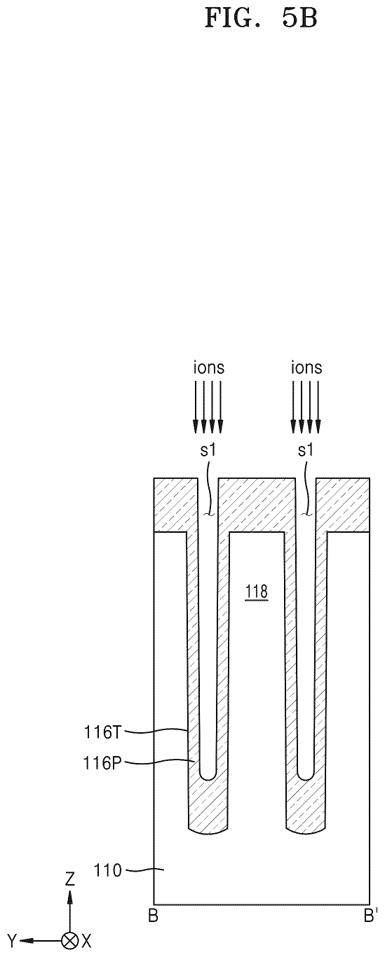

Referring to FIGS. 5A and 5B, an ion implantation process may be performed in the empty space s1 formed in the device separation trench 116T. In some embodiments, the implanted ion may be selected from Si, germanium (Ge), or argon (Ar), or a combination thereof. In some embodiments, the energy used to inject the ions may not be greater than about 2.5 keV. According to some embodiments, a concentration at which the ions are injected may range from about 0.1*10¹⁶ atom/cm² to about 0.2*10¹⁶ atom/cm².

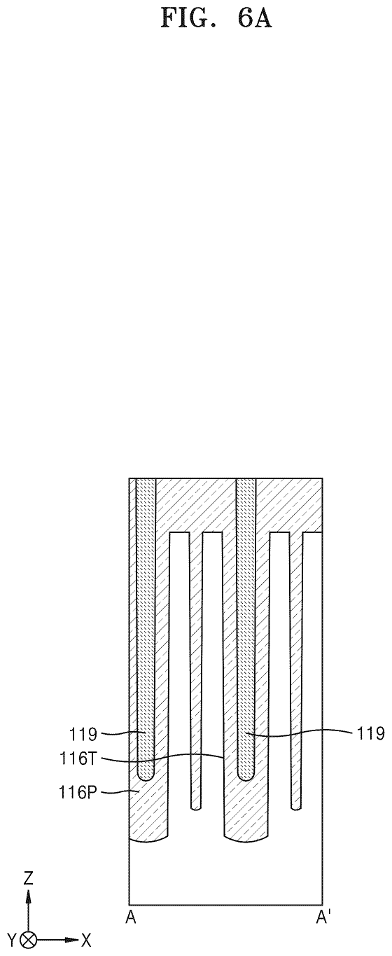

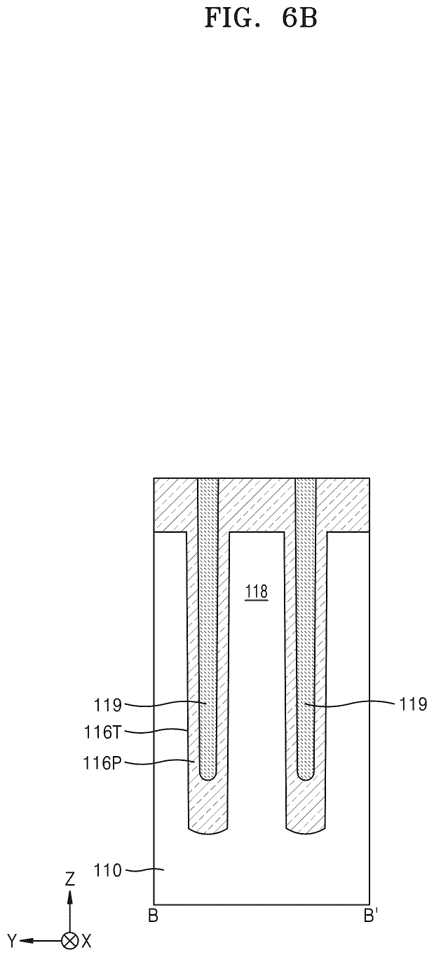

Referring to FIGS. 6A and 6B, an ion implantation layer 119 may be formed in the empty space (refer to s1 in FIGS. 5A and 5B) by using the ion implantation process performed with reference to FIGS. 5A and 5B. The ion implantation process performed with reference to FIGS. 5A and 5B may induce a swelling phenomenon of the silicon oxide material included in the device separation material layer 116P, and as a result, the empty space s1 remaining in the device separation material layer 116P may be filled with a doped layer. In an embodiment, an etching tolerance of the device separation material layer 116P may be enhanced by the ion implantation process. Accordingly, the semiconductor memory device 100 may prevent excessive recess formation by removing the empty space s1 and thus may secure the reliability of the semiconductor memory device.

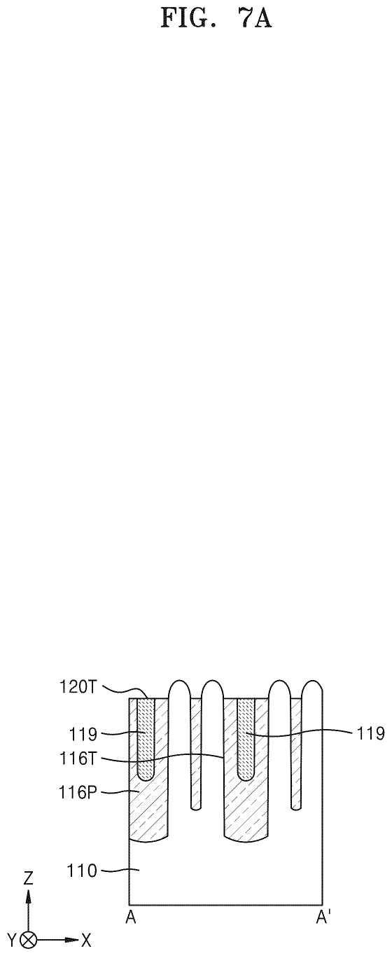

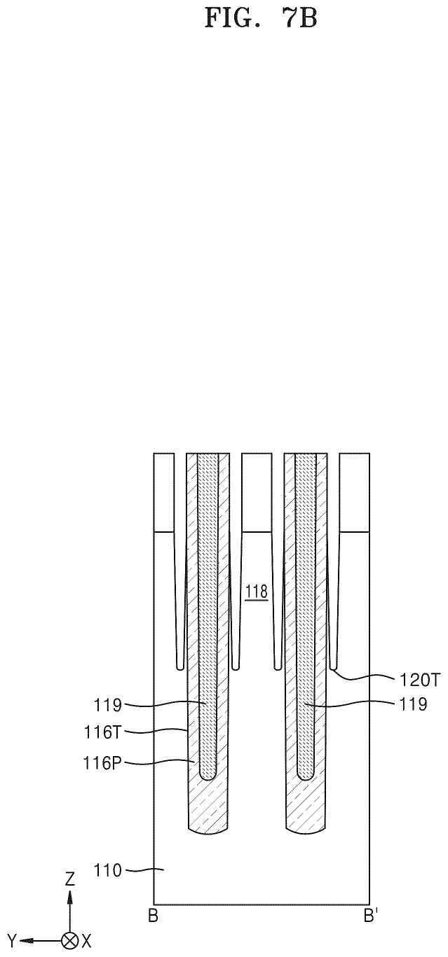

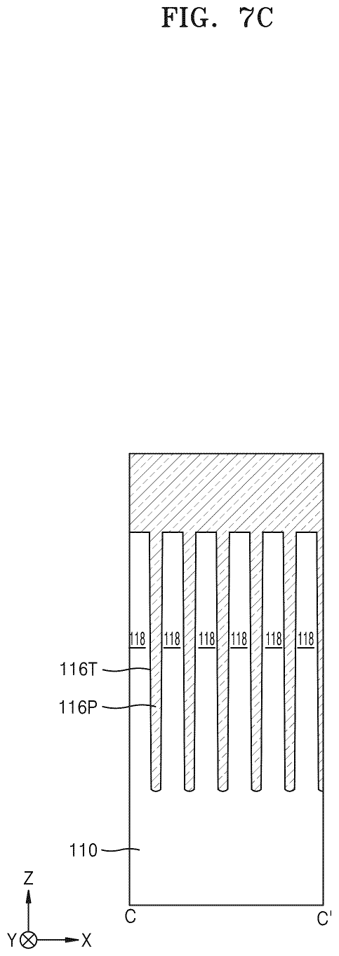

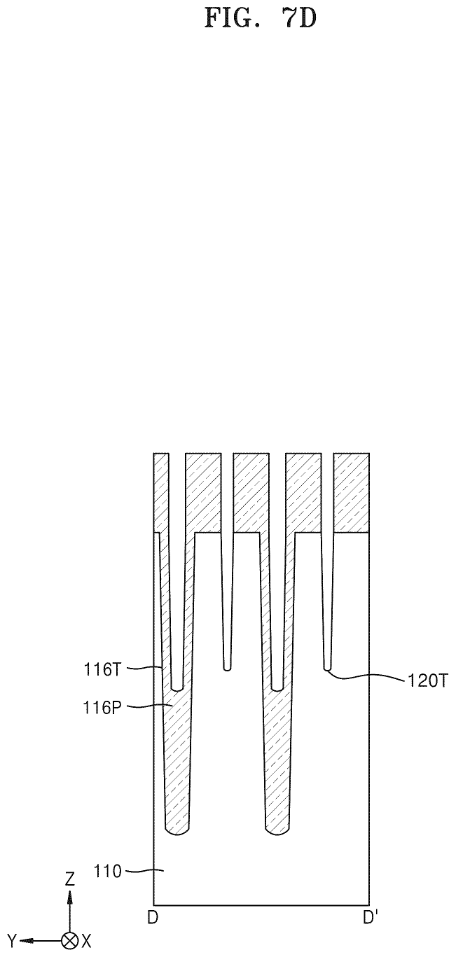

Referring to FIGS. 7A to 7D, a plurality of word line trenches 120T may be formed in the substrate 110, by removing portions of the plurality of active areas 118 and portions of the device separation material layer 116P and the ion implantation layer 119. The plurality of word line trenches 120T may extend in parallel with each other in the first horizontal direction (X direction), and may have a line shape in which each of the plurality of word line trenches 120T is arranged to cross each of the plurality of active areas 118. In some embodiments, the plurality of word line trenches 120T may have substantially equal intervals therebetween in the second horizontal direction (Y direction). In some embodiments, steps may be formed on lower surfaces of the plurality of word line trenches 120T.

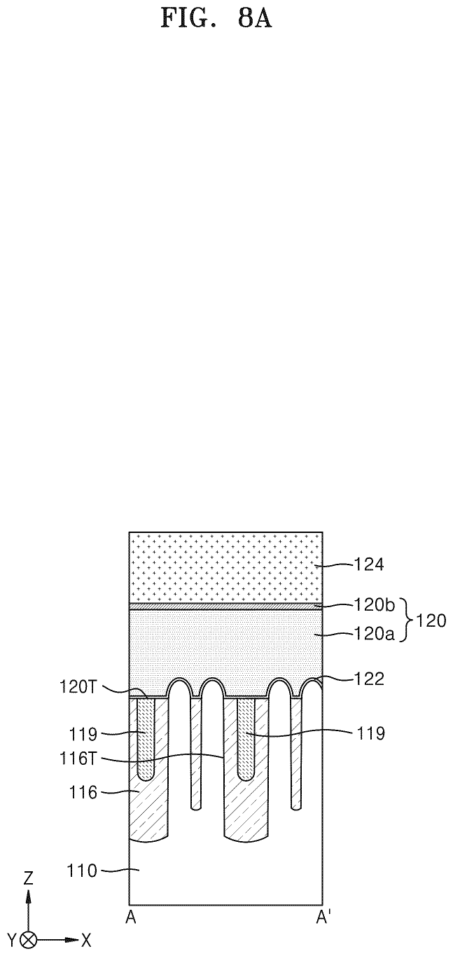

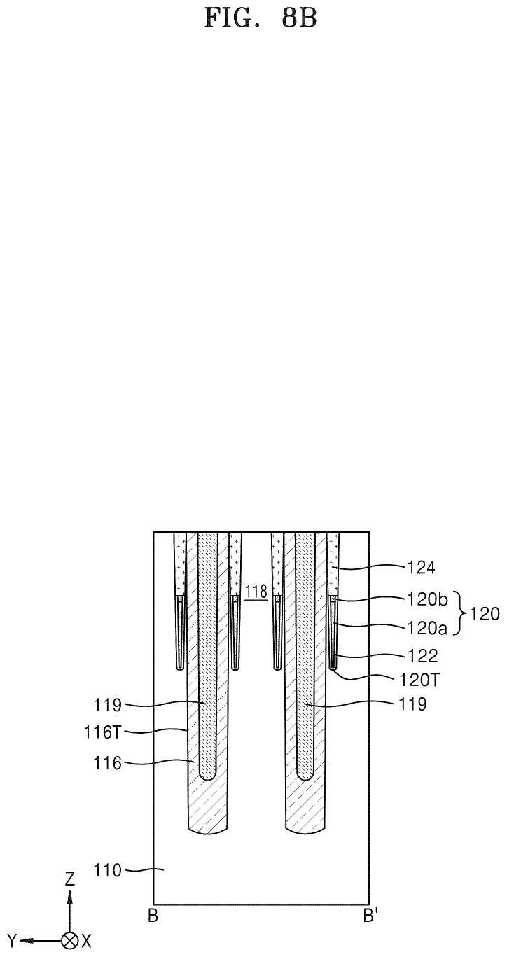

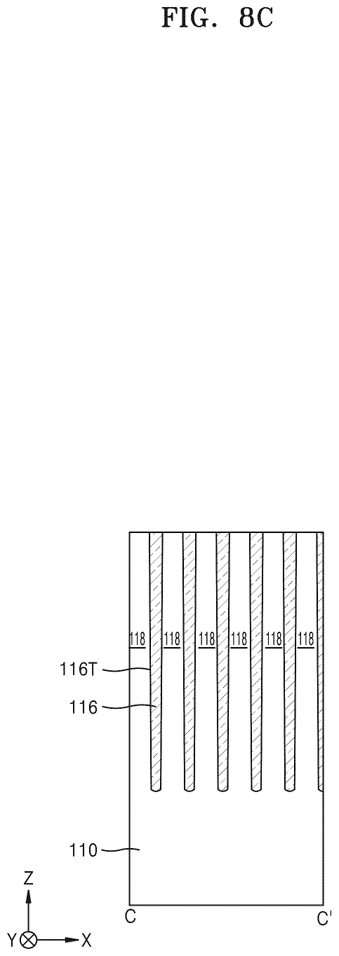

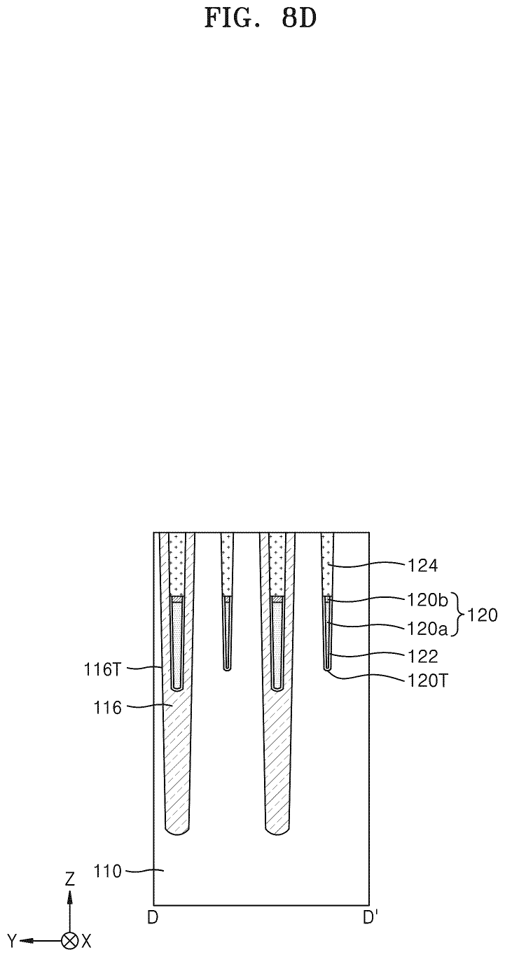

Referring to FIGS. 7A through 7D and 8A through 8D together, a plurality of gate dielectric layers 122, a plurality of word lines 120, and a plurality of buried insulating layers 124 may be sequentially formed inside a plurality of word line trenches 120T. The plurality of word lines 120 may respectively constitute the plurality of word lines WL illustrated in FIG. 2. The plurality of word lines 120 may extend in parallel with each other in the first horizontal direction (X direction), and may have a line shape in which each of the plurality of word lines 120 is arranged to cross the active area 118. In an embodiment, the plurality of word lines 120 may have substantially equal intervals therebetween in the second horizontal direction (Y direction). An upper surface of each of the plurality of word lines 120 may be at a lower level than the upper surface of the substrate 110 (see, e.g., FIGS. 8B, 8D). A bottom surface of the plurality of word lines 120 may have a concave-convex shape, and the plurality of active areas 118 may include transistors having a saddle fin structure (or saddle FinFETs).

Each of the plurality of word lines 120 may have a stacked structure including a lower word line layer 120a and an upper word line layer 120b. For example, the lower word line layer 120a may include a metal material, conductive metal nitride, or a combination thereof. In some embodiments, the lower word line layer 120a may include Ti, TiN, Ta, TaN, W, WN, TiSiN, WSiN, or a combination thereof. For example, the upper word line layer 120b may include doped polysilicon. In some embodiments, the lower word line layer 120a may include a core layer, and a barrier layer between the core layer and a gate dielectric layer 122.

In some embodiments, before or after the plurality of word lines 120 are formed, impurity ions may be implanted into a portion of the active area 118 of the substrate 110 on both sides of each of the plurality of word lines 120, and a source area and a drain area may be formed inside the plurality of active areas 118.

The gate dielectric layer 122 may include at least one of silicon oxide, silicon nitride, silicon oxynitride, oxide-nitride-oxide (ONO), or high-k dielectrics having a higher dielectric constant than silicon oxide. For example, the gate dielectric layer 122 may have a dielectric constant of about 10 to about 25.

Upper surfaces of the plurality of buried insulating layers 124 may be at substantially the same level as upper surfaces of the substrate 110. The buried insulating layer 124 may include at least one of silicon oxide, silicon nitride, or silicon oxynitride, or a combination thereof.

In the process of forming the plurality of gate dielectric layers 122, the plurality of word lines 120, and the plurality of buried insulating layers 124, portions of the upper sides of the device separation material layer 116P and the ion implantation layer 119 may be removed to form the device separation layer 116. The plurality of active areas 118 may be defined in the cell array area MCA in the substrate 110 by the device separation layer 116, and the plurality of logic active areas of the substrate 110 may be defined in the periphery area PCA.

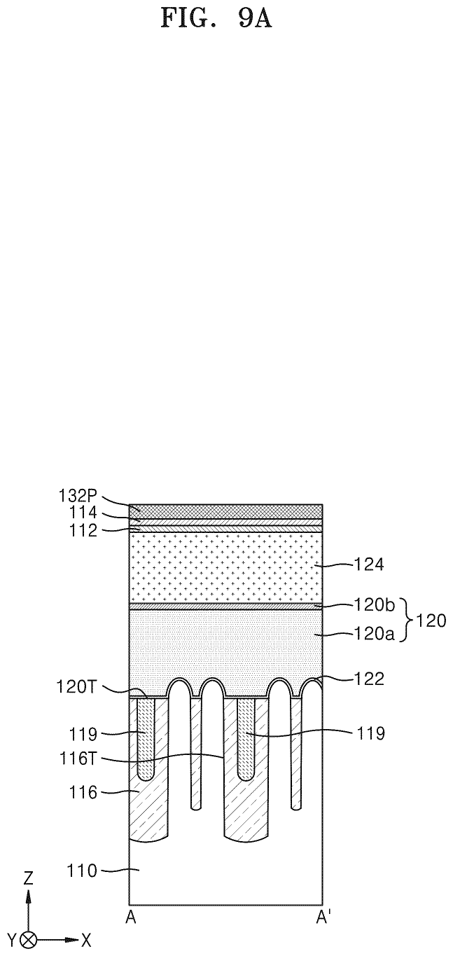

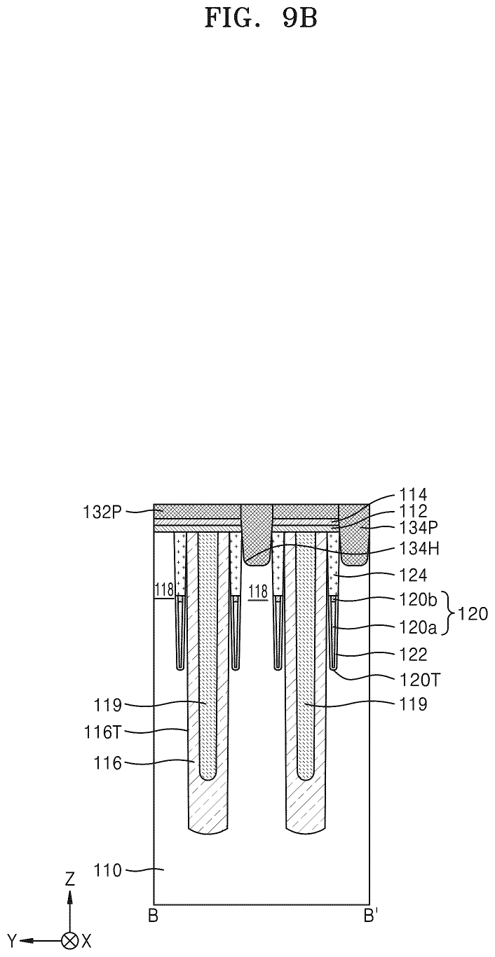

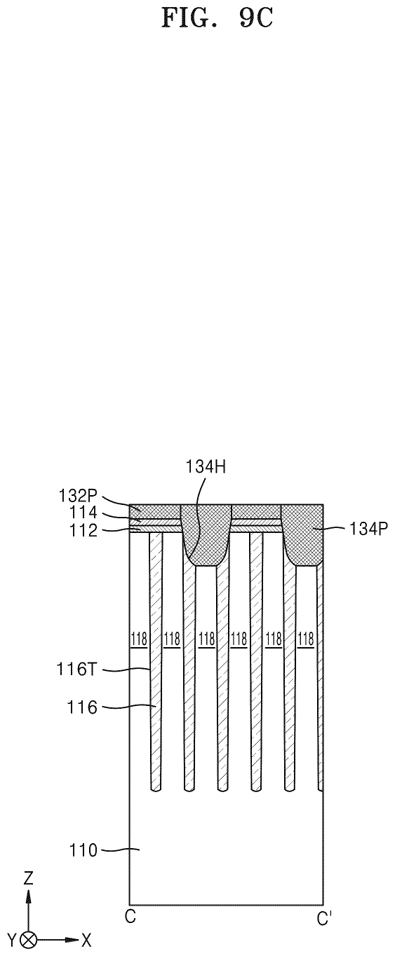

Referring to FIGS. 9A and 9D together, a first insulating layer pattern 112 and a second insulating layer pattern 114 covering the device separation layer 116, the plurality of active areas 118, and the plurality of buried insulating layers 124 may be formed. For example, the first and second insulating layer patterns 112 and 114 may include a silicon oxide layer, a silicon nitride layer, a silicon oxynitride layer, or a combination thereof. In some embodiments, the first and second insulating layer patterns 112 and 114 may be formed by stacking a plurality of insulating layers including the first insulating layer pattern 112 and the second insulating layer pattern 114. In some embodiments, the first insulating layer pattern 112 may include a silicon oxide layer, and the second insulating layer pattern 114 may include a silicon nitride layer. In other embodiments, the first insulating layer pattern 112 may include a non-metal dielectric layer, and the second insulating layer pattern 114 may include a metal dielectric layer.

Thereafter, after a conductive semiconductor layer 132P is formed on the first and second insulating layer patterns 112 and 114, a direct contact hole 134H penetrating the conductive semiconductor layer 132P and the first and second insulating layer patterns 112 and 114 and exposing the source area in the active area 118 may be formed, and a direct contact conductive layer 134P filling the direct contact hole 134H may be formed. In some embodiments, the direct contact hole 134H may extend into the active area 118, that is, into the source area. The conductive semiconductor layer 132P may include, for example, doped polysilicon. The direct contact conductive layer 134P may include, for example, doped polysilicon. In some embodiments, the direct contact conductive layer 134P may include an epitaxial silicon layer. In other embodiments, the direct contact conductive layer 134P may include a metal or a metal compound that is a conductive material. For example, the direct contact conductive layer 134P may include metal, such as Ti and/or W, or a conductive metal, which is a compound of a metal, such as Ti and/or W, and a non-metal, such as Si, C, B, and/or N. In some embodiments, the direct contact conductive layer 134P may include TiN, WC, or WSi.

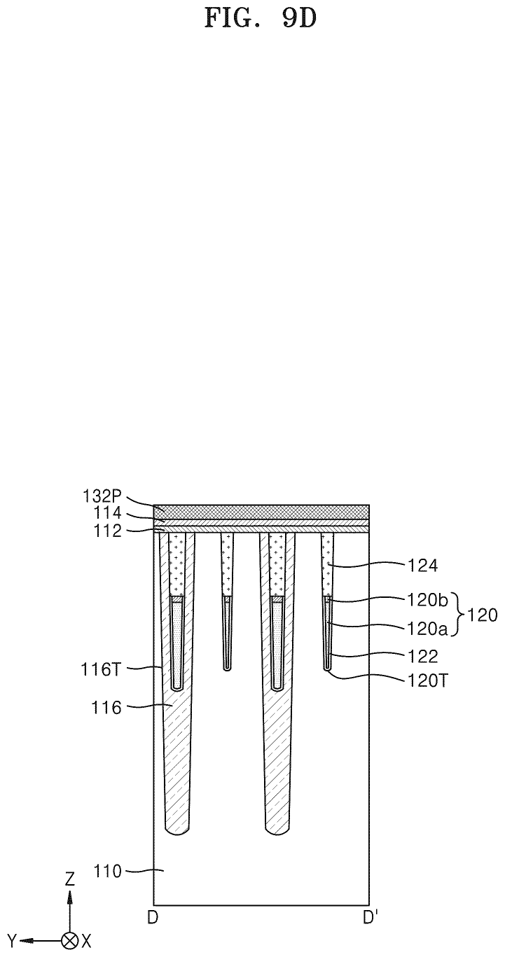

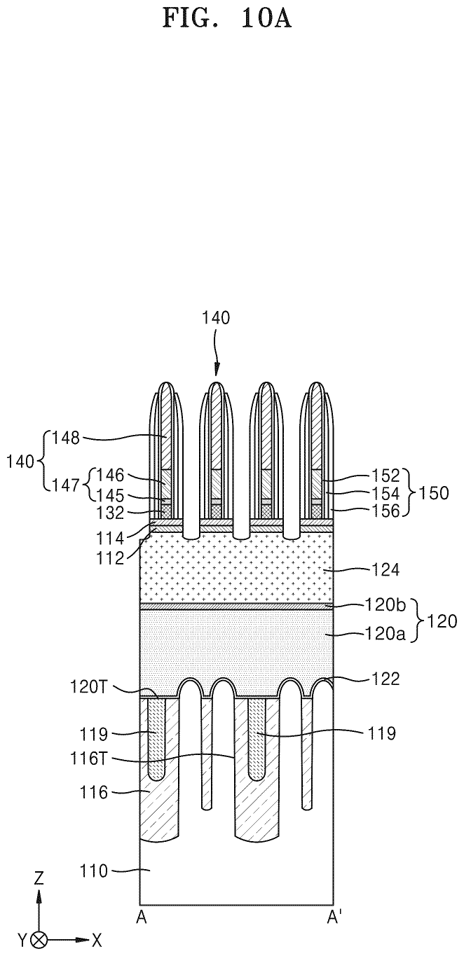

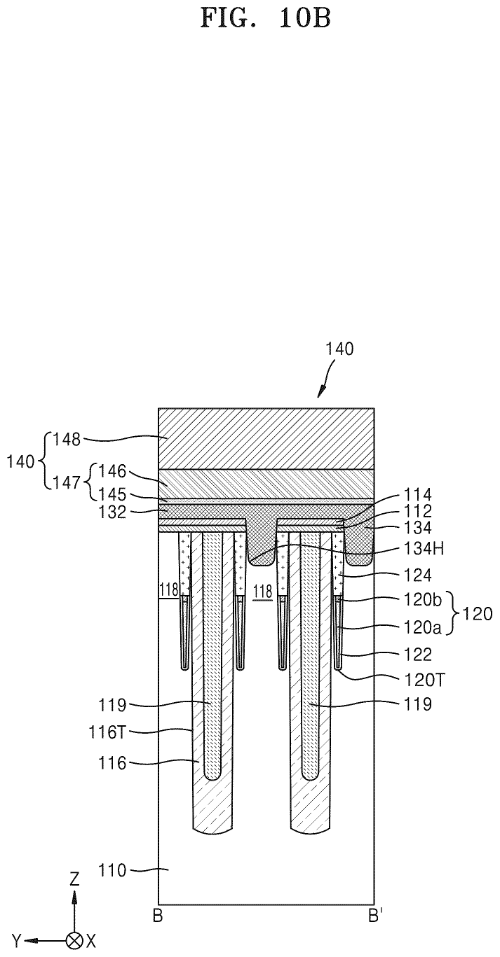

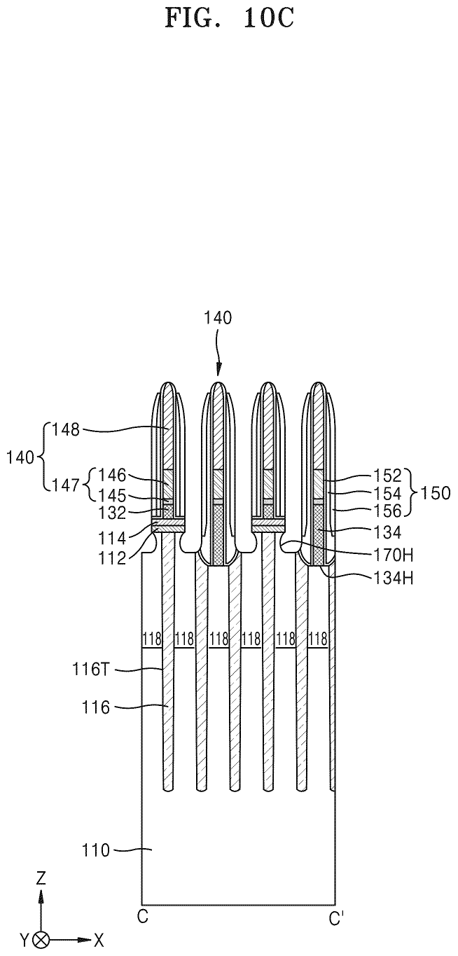

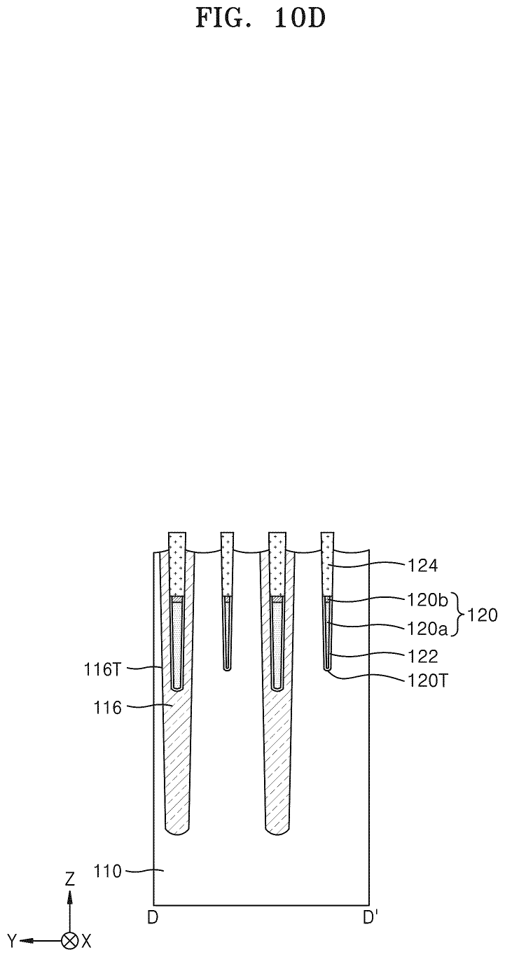

Referring to FIGS. 10A through 10D together with FIGS. 9A through 9D, a metal-based conductive layer and an insulating capping layer for covering the conductive semiconductor layer 132P and the direct contact conductive layer 134P and forming a bit line structure 140 may be sequentially formed. In some embodiments, the metal-based conductive layer may include a stacked structure including a first metal-based conductive layer and a second metal-based conductive layer. By etching the first metal-based conductive layer, the second metal-based conductive layer, and the insulating capping layer, a plurality of bit lines 147 including a first metal-based pattern 145 and a second metal-based pattern 146 having a line shape, and a plurality of insulating capping patterns 148 may be formed.

In some embodiments, the first metal-based pattern 145 may include titanium nitride (TiN) or Ti-Si-N (TSN) and the second metal-based pattern 146 may include W or tungsten silicide (WSiₓ). In some embodiments, the first metal-based pattern 145 may perform a function of a diffusion barrier. In some embodiments, the plurality of insulating capping lines 148 may include a silicon nitride layer.

One bit line 147 and one insulating capping line 148 covering the one bit line 147 may constitute one bit line structure 140. A plurality of bit line structures 140 each including the bit line 147 and the insulating capping line 148 covering the bit line 147 may extend in parallel with each other in the second horizontal direction (Y direction) in parallel with a main surface of the substrate 110. The plurality of bit lines 147 may respectively constitute the plurality of bit lines BL illustrated in FIG. 2. In some embodiments, the bit line structure 140 may further include a conductive semiconductor pattern 132, which is a portion of the conductive semiconductor layer 132P arranged between the first and second insulating layer patterns 112 and 114, and the first metal-based pattern 145.

In an etching process for forming the plurality of bit lines 147, a portion of the conductive semiconductor layer 132P which does not vertically overlap the bit line 147 and a portion of the direct contact conductive layer 134P may be removed together by the etching process to form a plurality of conductive semiconductor patterns 132 and a plurality of direct contact conductive patterns 134. In this case, the first and second insulating layer patterns 112 and 114 may function as an etching stop layer in an etching process of forming the plurality of bit lines 147, the plurality of conductive semiconductor patterns 132, and the plurality of direct contact conductive patterns 134. The plurality of direct contact conductive patterns 134 may respectively constitute the plurality of direct contacts DC illustrated in FIG. 2. The plurality of bit lines 147 may be electrically connected to the plurality of active areas 118 via the plurality of direct contact conductive patterns 134, respectively. The conductive semiconductor pattern 132 may include, for example, doped polysilicon. The direct contact conductive pattern 134 may include doped polysilicon, a metal, or a metal compound that includes a conductive material. For example, the direct contact conductive pattern 134 may include a one-bit metal, such as Ti and/or W, or a conductive metal, which is a compound of a metal, such as Ti and/or W, and a non-metal, such as Si, C, B, and/or N. In some embodiments, the direct contact conductive pattern 134 may include TiN, WC, or WSi.

Both sidewalls of each of the plurality of bit line structures 140 may be covered by an insulating spacer structure 150. Each of the plurality of insulating spacer structures 150 may include a first insulating spacer 152, a second insulating spacer 154, and a third insulating spacer 156. The second insulating spacer 154 may include a material having a lower dielectric constant than the first insulating spacer 152 and the third insulating spacer 156. In some embodiments, the first insulating spacer 152 and the third insulating spacer 156 may include a nitride layer, and the second insulating spacer 154 may include an oxide layer. In some embodiments, the first insulating spacer 152 and the third insulating spacer 156 may include a nitride layer, and the second insulating spacer 154 may include a material having an etching selectivity with respect to the first insulating spacer 152 and the third insulating spacer 156. For example, when the first insulating spacer 152 and the second insulating spacer 156 include a nitride layer, the second insulating spacer 154 may include an oxide layer, but may be removed in a subsequent process to become an air spacer.

A plurality of buried contact holes 170H may be formed between each of the plurality of bit lines 140. The plurality of buried contact holes 170H may have an inner space limited by the insulating spacer structure 150, which covers sidewalls of each of two neighboring bit lines 147 between two neighboring bit lines 147 among the plurality of bit lines 147, and by the active area 118.

The plurality of buried contact holes 170H may be formed by removing portions of the first and second insulating layer patterns 112 and 114 and the active area 118 by using the plurality of insulating capping lines 148 and the insulating spacer structure 150, which covers both sidewalls of each of the plurality of bit line structures 140, as etching masks. In some embodiments, after performing first an anisotropic etching process of removing portions of the first and second insulating layer patterns 112 and 114 and the active area 118 by using the plurality of insulating capping lines 148 and the insulating spacer structure 150, which covers both sidewalls of each of the plurality of bit line structures 140, as etching masks, and by performing an isotropic etching process of further removing the other portions of the active area 118, the plurality of buried contact holes 170H may be formed to have an expanded space that is limited by the active area 118.

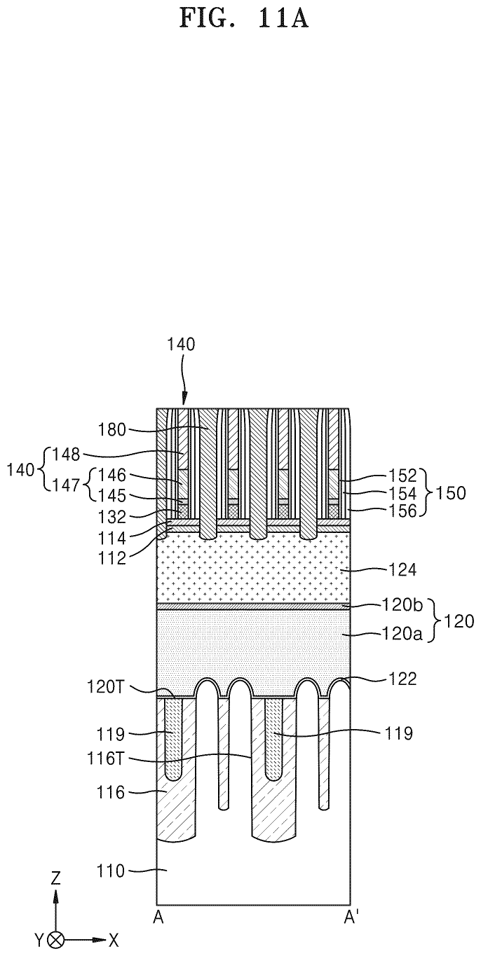

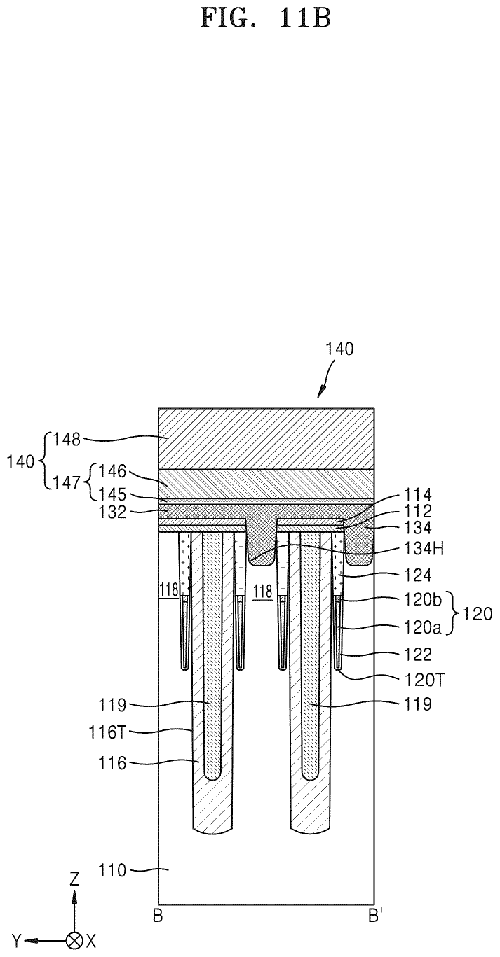

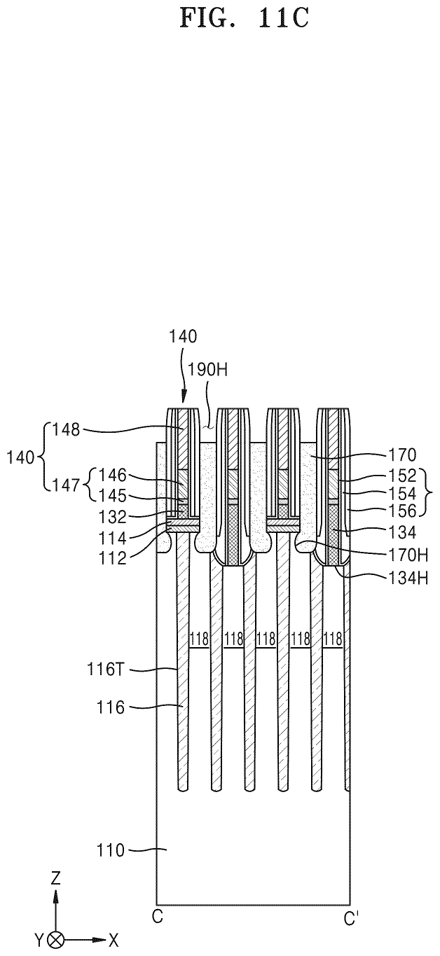

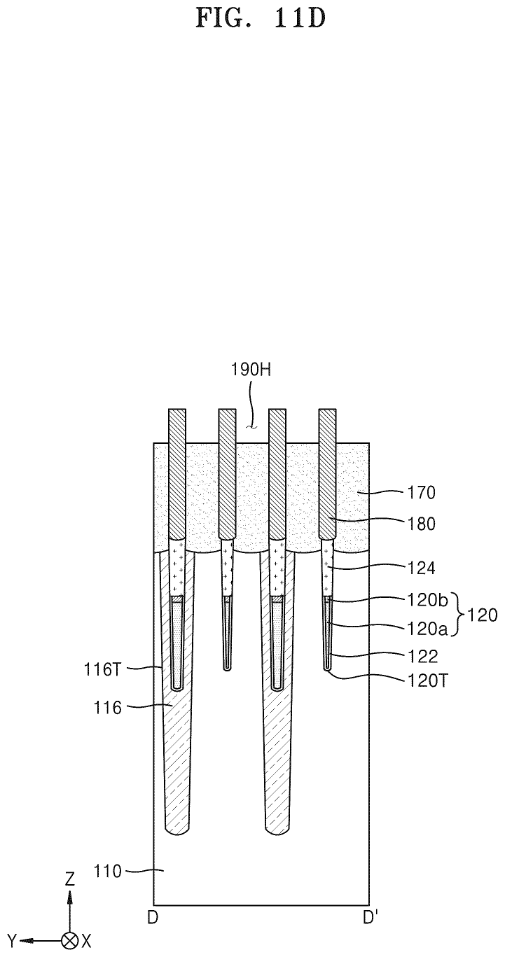

Referring to FIGS. 11A through 11D together, a plurality of buried contacts 170 and a plurality of insulating fences 180 may be formed in a space between the plurality of insulating spacer structures 150 covering both sidewalls of each of the plurality of bit line structures 140. The plurality of buried contacts 170 and the plurality of insulating fences 180 may be alternately arranged along a space between a pair of insulating spacer structures 150 which face each other among the plurality of insulating spacer structures 150 covering both sidewalls of the plurality of bit line structures 140, that is, in the second horizontal direction (Y direction). For example, the plurality of buried contacts 170 may include polysilicon. For example, the plurality of insulating fences 180 may include a nitride layer.

In some embodiments, the plurality of buried contacts 170 may be arranged in a line in the first horizontal direction (X direction) and the second horizontal direction (Y direction), respectively. Each of the plurality of buried contacts 170 may extend from the active area 118 in the vertical direction (Z direction) perpendicular to the substrate 110. The plurality of buried contacts 170 may respectively constitute the plurality of buried contacts BC illustrated in FIG. 2.

The plurality of buried contacts 170 may be in a space limited by the plurality of insulating spacer structures 150, which cover both sidewalls of the plurality of insulating fences 180 and the plurality of bit line structures 140. The plurality of buried contacts 170 may fill a lower portion of the space between the plurality of insulating spacer structures 150 covering both sidewalls of each of the plurality of bit line structures 140.

A level of an upper surface of the plurality of buried contacts 170 may be lower than a level of an upper surface of the plurality of insulating capping lines 148. An upper surface of the plurality of insulating fences 180 and an upper surface of the plurality of insulating capping lines 148 may be at the same level with respect to the vertical direction (Z direction).

A plurality of landing pad holes 190H may be defined by the plurality of insulating spacer structures 150 and the plurality of insulating fences 180. The plurality of buried contacts 170 may be respectively exposed at lower surfaces of the plurality of landing pad holes 190H.

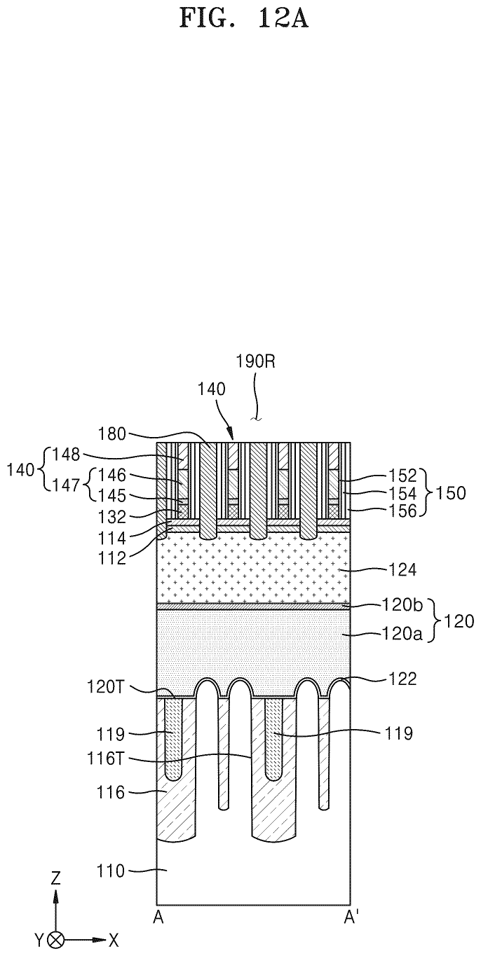

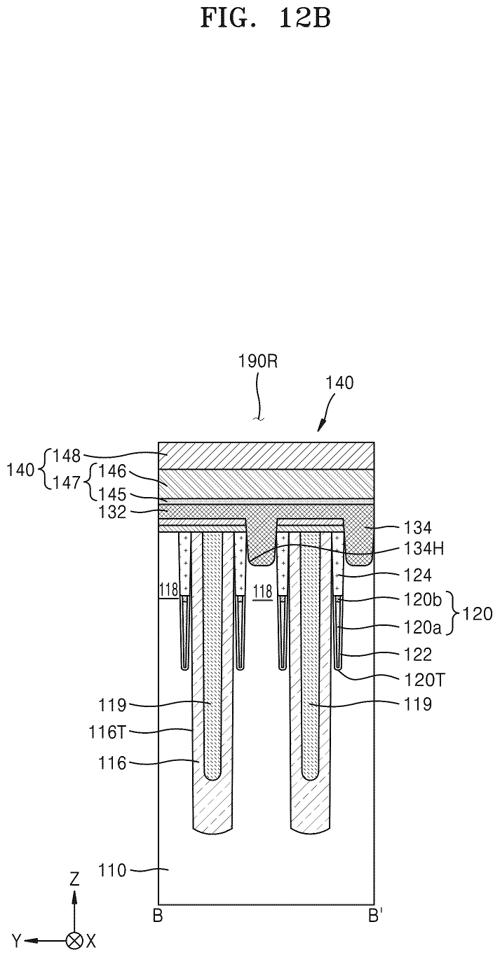

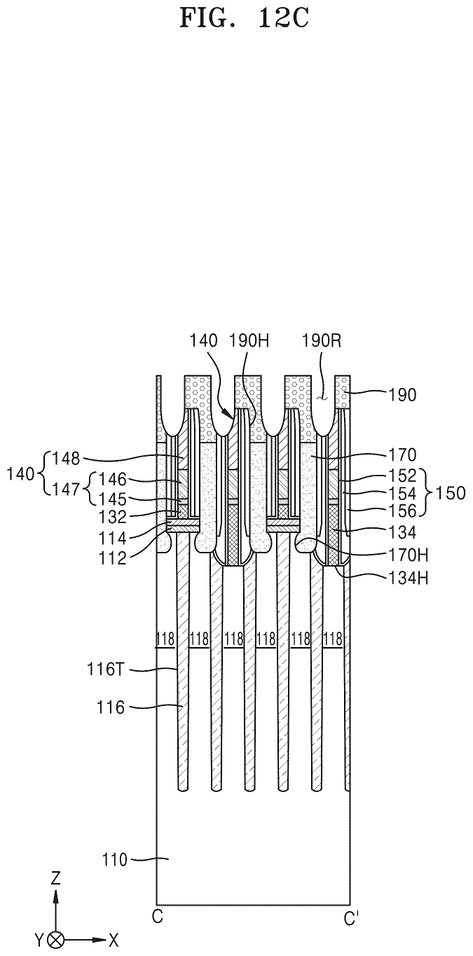

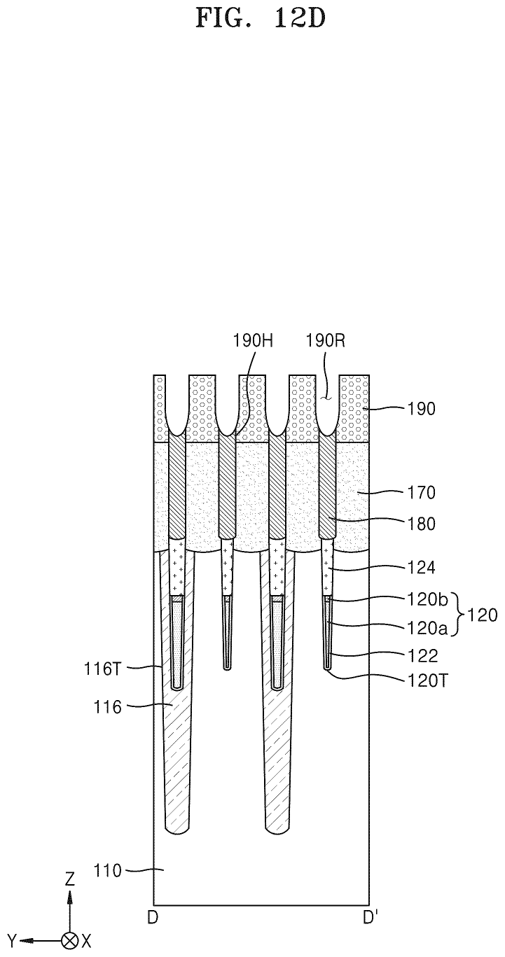

Referring to FIGS. 12A through 12D together, a landing pad material layer filling the plurality of landing pad holes 190H and covering the plurality of bit line structures 140 may be formed. In some embodiments, the landing pad material layer may include a conductive barrier layer and a conductive pad material layer on the conductive barrier layer. For example, the conductive barrier layer may include a metal, a conductive metal nitride, or a combination thereof. In some embodiments, the conductive barrier layer may have a Ti/TiN stacked structure. In some embodiments, the conductive pad material layer may include W.

In some embodiments, a metal silicide layer may be formed on the plurality of buried contacts 170 before the landing pad material layer is formed. The metal silicide layer may be arranged between the plurality of buried contacts 170 and the landing pad material layer. The metal silicide layer may include cobalt silicide (CoSiₓ), nickel silicide (NiSiₓ), or manganese silicide (MnSiₓ), but is not limited thereto.

Thereafter, a portion of the landing pad material layer may be removed to fill at least a portion of the plurality of landing pad holes 190H, and extend onto the plurality of bit line structures 140 to form a plurality of landing pads 190 separated from each other by a recess portion 190R.

The plurality of landing pads 190 may be spaced apart from each other with the recess portion 190R therebetween. The plurality of landing pads 190 may be respectively arranged on the plurality of buried contacts 170 and may respectively extend onto the plurality of bit line structures 140. In some embodiments, the plurality of landing pads 190 may respectively extend onto the plurality of bit lines 147. The plurality of landing pads 190 may be on the plurality of buried contacts 170, and the plurality of buried contacts 170 may be electrically and respectively connected to the plurality of landing pads 190 corresponding thereto. The buried contact 170 and the landing pad 190 corresponding to each other may be referred to as contact plugs together. The plurality of landing pads 190 may be connected to the active area 118 via the plurality of buried contacts 170. The plurality of landing pads 190 may respectively constitute the plurality of landing pads LP illustrated in FIG. 2.

The buried contact 170 may be arranged between two bit line structures 140 adjacent to each other, and the landing pad 190 may extend, from a space between two adjacent bit line structures 140 with the buried contact 170 therebetween, onto one bit line structure 140.

Referring to FIGS. 13A through 13D, an insulating structure 195 filling the recess portion 190R may be formed. In some embodiments, the insulating structure 195 may include an interlayer insulating layer and an etching stop layer. For example, the interlayer insulating layer may include an oxide and the etching stop layer may include a nitride. FIGS. 13A though 13D illustrate that an upper surface of the insulating structure 195 and an upper surface of the landing pad 190 are at the same level, but embodiments are not limited thereto.

A plurality of lower electrodes 210 respectively connected to the plurality of landing pads 190 may be formed. The plurality of lower electrodes 210 may be respectively and electrically connected to the plurality of landing pads 190. Each of the plurality of lower electrodes 210 may have a column shape, that is, a pillar shape, with the filled inside having a circular horizontal cross-section, but embodiments are not limited thereto. In some embodiments, each of the plurality of lower electrodes 210 may have a cylinder shape having a closed lower portion thereof. In some embodiments, the plurality of lower electrodes 210 may be arranged in a honeycomb zigzag shape with respect to the first horizontal direction (X direction) or the second horizontal direction (Y direction). In some other embodiments, the plurality of lower electrodes 210 may be arranged in a line matrix shape in each of the first horizontal direction (X direction) and the second horizontal direction (Y direction). The plurality of lower electrodes 210 may include, for example, silicon doped with impurities, a metal, such as W and/or copper, or a conductive metal compound such as titanium nitride.

A capacitor dielectric layer 220 and an upper electrode 230 are sequentially formed on the plurality of lower electrodes 210 to form the semiconductor memory device 100. The capacitor dielectric layers 220 and the upper electrodes 230 on the plurality of lower electrodes 210 may constitute a plurality of capacitor structures 200. The capacitor dielectric layer 220 may conformally cover surfaces of the plurality of lower electrodes 210. In some embodiments, the capacitor dielectric layer 220 may be integrally formed to cover the plurality of lower electrodes 210 in a certain area, for example, in one cell array area (refer to MCA in FIG. 2).

The capacitor dielectric layer 220 may include, for example, TaO, TaAlO, TaON, AlO, AlSiO, HfO, HfSiO, ZrO, ZrSiO, TiO, TiAlO, (Ba,Sr)TiO (BST), SrTiO (STO), BaTiO (BTO), (Pb,Zr,Ti) (PZT)O, (Pb,La)(Zr,Ti)O, Ba(Zr,Ti)O, Sr(Zr,Ti)O, or a combination thereof.

The upper electrode 230 may include, for example, W, Ru, RuO, Pt, PtO, Ir, IrO, SrRuO (SRO), (Ba,Sr)RuO (BSRO),CaRuO (CRO), BaRuO, or La(Sr,Co)O, etc. In some embodiments, the upper electrode 230 may include a metal material. For example, the upper electrode 230 may include W.

In the semiconductor memory device 100 illustrated in FIGS. 3A through 13D, the ion implantation layer 119 may be formed by performing an ion implantation process after the device separation material layer 116P is completely formed inside the device separation trench 116T. However, in some embodiments, the ion implantation layer 119 may be obtained by forming the device separation material layer in the remaining space of the device separation trench 116T after partially forming the device separation material layer inside the device separation trench 116T and performing the ion implantation process into the empty seam. The ion implantation process performed in the processes described above may be preceded by implanting the same type element at the same energy and the same concentration as described with reference to FIGS. 5A, 5B, 6A, and 6B.

In the semiconductor memory device 100 according to various embodiments, by forming the device separation material layer 116P in the device separation trench 116T and performing the ion implantation process into the empty seam resulted therefrom, the swelling phenomenon of a semiconductor oxide material included in the device separation material layer 116P may be induced and at the same time, the etching tolerance of the device separation material layer 116P may be reinforced. Thus, in the semiconductor memory device 100 according to various embodiments, the empty seam, which may remain between the device separation layers 116, may be removed, and at the same time, a phenomenon of an excessive recess formation in the subsequent processes may be prevented, defects may not occur even at a high degree of integration, and therefore, the operation reliability may be secured.

While various embodiments have been particularly shown and described with reference to the drawings thereof, it will be understood that various change in form and details may be made therein without departing from the spirit and scope of the following claims.

What is claimed is:

1. A semiconductor memory device comprising:
a substrate having a plurality of active areas defined by a device separation trench;
a device separation material layer that fills the device separation trench and that is formed of a first material;
a word line trench that crosses the plurality of active areas and the device separation material layer and that extends in a first horizontal direction;
a gate dielectric layer covering an inner wall of the word line trench; and
a word line that fills a portion of the word line trench on the gate dielectric layer,
wherein the device separation material layer comprises a doped layer inside the device separation material layer, the doped layer including a second material different from the first material.

2. The semiconductor memory device of claim 1, wherein
the first material comprises silicon oxide, and
the second material comprises a material of silicon (Si), germanium (Ge), argon (Ar), or a combination thereof.

3. The semiconductor memory device of claim 1, wherein the second material forms the doped layer as a result of an ion implantation into the device separation material layer.

4. The semiconductor memory device of claim 3, wherein the second material is implanted into the device separation material layer with an energy not greater than about 2.5 keV.

5. The semiconductor memory device of claim 3, wherein a concentration of the second material implanted into the device separation material layer is in a range of about 0.1*10¹⁶ atom/cm² to about 0.2*10¹⁶ atom/cm².

6. The semiconductor memory device of claim 1, wherein the first material does not comprise silicon nitride.

7. The semiconductor memory device of claim 1, wherein an upper surface of the doped layer is coplanar with an upper surface of the device separation material layer in a vertical direction.

8. The semiconductor memory device of claim 1, wherein a lower surface of the doped layer is at a higher level than a lower surface of the device separation material layer in a vertical direction.

9. The semiconductor memory device of claim 1, wherein:
at all vertical levels in an area in which the doped layer is formed, a horizontal cross-sectional area of the doped layer is within a horizontal cross-sectional area of the device separation material layer.

10. The semiconductor memory device of claim 1, further comprising:
a plurality of bit lines respectively arranged on the plurality of active areas and extending in a second horizontal direction orthogonal to the first horizontal direction;
a gate line arranged in at least one active area among the plurality of active areas;
a plurality of landing pads that fill an upper side portion of a space between the plurality of bit lines and that respectively extend onto the plurality of bit lines; and
a plurality of capacitor structures including an upper electrode, a plurality of lower electrodes respectively in contact with the plurality of landing pads, and a capacitor dielectric layer arranged between the upper electrode and the plurality of lower electrodes.

11. A semiconductor memory device comprising:
a substrate including a cell array area and a periphery circuit area;
a plurality of active areas defined by a device separation trench in the cell array area;
a device separation material layer that fills the device separation trench;
a word line trench that crosses the plurality of active areas and the device separation material layer and that extends in a first horizontal direction;
a gate dielectric layer covering an inner wall of the word line trench; and
a word line that fills a portion of the word line trench on the gate dielectric layer,
wherein the device separation material layer comprises a recess area formed in a vertical direction that is perpendicular to the substrate, and
the recess area is filled with an ion implantation layer.

12. The semiconductor memory device of claim 11, wherein the ion implantation layer comprises a material of silicon (Si), germanium (Ge), argon (Ar), or a combination thereof.

13. The semiconductor memory device of claim 11, wherein a concentration of elements included in the ion implantation layer is in a range of about 0.1*10¹⁶ atom/cm² to about 0.2*10¹⁶ atom/cm².

14. The semiconductor memory device of claim 11, wherein:
a width of a horizontal cross-sectional area of the recess area is not greater than a width of a horizontal cross-sectional area of the device separation material layer, and an upper surface of the recess area is coplanar with an upper surface of the device separation material layer.

15. The semiconductor memory device of claim 11, wherein a width of the recess area in the vertical direction is less than a width of the device separation material layer in the vertical direction.

16. The semiconductor memory device of claim 11, wherein the device separation material layer comprises silicon oxide but not silicon nitride.

17. The semiconductor memory device of claim 11, wherein the recess area is physically spaced apart from the substrate.

18. A semiconductor memory device comprising:
a substrate having a cell array area including a plurality of active areas defined by a device separation trench, a periphery circuit area in which at least one logic active area is defined, and an interface area between the cell array area and the periphery circuit area;
a device separation material layer that fills the device separation trench in the cell array area;
a plurality of word lines respectively crossing the plurality of active areas and extending in a first horizontal direction;
a plurality of bit lines respectively arranged in the plurality of active areas and extending in a second horizontal direction that is orthogonal to the first horizontal direction;
a gate line arranged in the at least one logic active area;
a plurality of buried contacts that fill a lower side portion of a space between the plurality of bit lines and that are respectively connected to the plurality of active areas;
a plurality of landing pads that fill an upper side portion between the plurality of bit lines and that respectively extend onto the plurality of bit lines; and
a plurality of capacitor structures including an upper electrode, a plurality of lower electrodes respectively in contact with the plurality of landing pads, and a capacitor dielectric layer arranged between the upper electrode and the plurality of lower electrodes,
wherein the device separation material layer comprises an ion implantation layer that extends into the device separation material layer to a first depth from an upper surface of the device separation material layer toward the substrate, and
wherein a horizontal cross-section of the ion implantation layer is within a horizontal cross-section of the device separation material layer, and the first depth is less than a thickness of the device separation material layer in a vertical direction.

19. The semiconductor memory device of claim 18,
wherein the ion implantation layer comprises a material of silicon (Si), germanium (Ge), argon (Ar), or a combination thereof, and
wherein a doping concentration of the material is in a range of about 0.1*10¹⁶ atom/cm² to about 0.2*10¹⁶ atom/cm².

20. The semiconductor memory device of claim 18. wherein the device separation material layer comprises silicon oxide but not silicon nitride.
